(19) United States
(12) Patent Application Publication
(10) Pub. No.: US 2021/0066124 A1
(43) Pub. Date: Mar. 4, 2021

(54) SEMICONDUCTOR DEVICE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Tiantian ZHANG, Shanghai (CN); Zengsheng XU, Shanghai (CN); Jingjing TAN, Shanghai (CN)

(21) Appl. No.: 17/006,000

(22) Filed: Aug. 28, 2020

(30) Foreign Application Priority Data
Sep. 4, 2019 (CN) 201910832664.7

(51) Int. Cl. H01L 21/768; H01L 23/522; H01L 23/532

(52) U.S. Cl. CPC H01L 21/76846; H01L 21/76802; H01L 23/53209; H01L 23/5226; H01L 21/76871

(57) ABSTRACT

A semiconductor device and a method for forming the semiconductor device are provided. The method includes providing a substrate and forming an interlayer dielectric layer on the substrate. The method also includes forming a contact hole exposing a portion of the surface of the substrate by etching the interlayer dielectric layer. In addition, the method includes forming an adhesion layer at a bottom and on a sidewall of the contact hole, and forming a metal seed layer at a bottom and on a sidewall of the adhesion layer by a selective growth method. Further, the method includes forming a metal layer filling the contact hole on the metal seed layer.

### CROSS-REFERENCES TO RELATED APPLICATIONS

This application claims the priority of Chinese patent application No. 201910832664.7, filed on Sep. 4, 2019, the entirety of which is incorporated herein by reference.

### FIELD OF THE DISCLOSURE

The present disclosure generally relates to the field of semiconductor manufacturing technology and, more particularly, relates to a semiconductor device and a fabrication method thereof.

### BACKGROUND

With rapid development of semiconductor manufacturing technology, semiconductor devices have been developed towards substantially high component density and substantially high degree of integration. As the most basic semiconductor devices, transistors are currently being widely used. In order to adapt to a smaller critical dimension, a channel length of a traditional planar metal-oxide-semiconductor field-effect transistor (MOSFET) is also increasingly smaller. However, as a channel length of a device keeps shrinking, the channel control capability of a gate structure deteriorates, and there is increasing difficulty in pinching the channel off by a gate voltage, resulting in a higher risk of subthreshold leakage, that is, the so-called short-channel effect (SCE). Consequently, the electrical performance of the semiconductor device may be degraded.

When forming a semiconductor device, contact holes need to be formed for a source region, a drain region and a gate structure of the transistor, and are filled with conductive materials (e.g., metals) to form conductive plugs for electrical connection between transistors and interconnection metal layers. However, at present, the formation quality of an interface between a metal layer and a contact hole is substantially poor, and hole defects are formed at the interface between the metal layer and the contact hole. Therefore, the semiconductor device tends to have leakage or failure issues during operation, which limits the application of the semiconductor device.

How to enable the interface between the metal layer and the contact hole to have desired formation quality and to ensure that the formed semiconductor devices have desired electrical performance is an urgent issue needs to be solved. The disclosed methods and device structures are directed to solve one or more problems set forth above and other problems.

### BRIEF SUMMARY OF THE DISCLOSURE

To address the problems described above, embodiments and implementations of the present disclosure provide a semiconductor device and a fabrication method thereof to enable the interface between the metal layer and the contact hole to have desired formation quality, thereby ensuring the formed semiconductor device has desired electrical performance and yield.

One aspect of the present disclosure includes a method for forming a semiconductor device, including: providing a substrate; forming an interlayer dielectric layer on the substrate; forming a contact hole exposing a portion of the surface of the substrate by etching the interlayer dielectric layer; forming an adhesion layer at a bottom and on a sidewall of the contact hole; forming a metal seed layer at a bottom and on a sidewall of the adhesion layer by a selective growth method; and forming a metal layer filling the contact hole on the metal seed layer.

Optionally, process parameters of the selective growth method include: an organic source including (C₅H₅)Co(CO)₂; a reaction gas including hydrogen, ammonia and argon, where a flow rate of hydrogen is in a range of approximately 1000 sccm-8000 sccm, a flow rate of ammonia is in a range of approximately 1000 sccm-5000 sccm, and a flow rate of argon is in a range of approximately 10 sccm-500 sccm; a source RF (radio frequency) power in a range of approximately 100 W-2000 W; a temperature in a range of approximately 100° C.-400° C.; and a pressure in a range of approximately 10 Torr-40 Torr.

Optionally, the metal seed layer is made of cobalt.

Optionally, the metal layer is made of cobalt.

Optionally, the metal layer is formed by an electrochemical plating method.

Optionally, the adhesion layer is one of a single-layer adhesion layer and a multi-layer adhesion layer.

Optionally, when the adhesion layer is the multi-layer adhesion layer, the multi-layer adhesion layer includes a reactive metal layer and a first diffusion barrier layer, where forming the multi-layer adhesion layer includes: forming the reactive metal layer at the bottom and on the sidewall of the contact hole, and forming the first diffusion barrier layer on the reactive metal layer.

Optionally, after forming the first diffusion barrier layer, the method further includes forming a second diffusion barrier layer on the first diffusion barrier layer.

Optionally, the single-layer adhesion layer is made of tungsten, tantalum, titanium, or a combination thereof.

Optionally, when the single-layer adhesion layer is made of one of tungsten and tantalum, before forming the single-layer adhesion layer, the method further includes forming a silicide layer on the substrate in the contact hole.

Optionally, when the single-layer adhesion layer is made of titanium, after forming the metal layer, the method further includes forming a silicide layer on the substrate in the contact hole.

Optionally, forming the single-layer adhesion layer includes an atomic layer deposition method.

Another aspect of the present disclosure includes a semiconductor device, including: a substrate; an interlayer dielectric layer on the substrate, where the interlayer dielectric layer includes a contact hole exposing a portion of the surface of the substrate; an adhesion layer at a bottom and on a sidewall of the contact hole in the interlayer dielectric layer; a metal seed layer at a bottom and on a sidewall of the adhesion layer; and a metal layer on the metal seed layer, where the metal layer fills the contact hole.

Optionally, the metal seed layer is made of cobalt.

Optionally, the metal layer is made of cobalt.

Optionally, the adhesion layer is one of a single-layer adhesion layer and a multi-layer adhesion layer.

Optionally, the multi-layer adhesion layer includes a reactive metal layer and a first diffusion barrier layer.

Optionally, the semiconductor device further includes a second diffusion barrier layer on the first diffusion barrier layer.

Optionally, the single-layer adhesion layer is made of tungsten, tantalum, titanium, or a combination thereof.

Optionally, the semiconductor device further includes a silicide layer on the substrate and under the adhesion layer.

The disclosed embodiments may have following beneficial effects. The metal seed layer may be formed at the bottom and on the sidewall of the contact hole by a selective growth method. The formed metal seed layer may be effectively adhered to the adhesion layer. When forming the metal layer on the metal seed layer, the metal seed layer may not be easily peeled off from the adhesion layer. Therefore, when forming the metal layer, the interface between the metal layer and the contact hole may have a desired formation quality, and hole defects may not be formed at the interface, thereby improving the device performance and yield of the formed semiconductor device.

The surface of the metal seed layer formed by the selective growth method may have similar properties to the surface of the adhesion layer. When forming the metal seed layer, an adsorption force for adsorbing the metal seed layer may be formed at the surface of the adhesion layer. Therefore, the metal seed layer may substantially easily fill the bottom of the contact hole, and the formed metal seed layer may have desired adhesion quality. Meanwhile, the adhesive force between the adhesion layer and the metal seed layer may be substantially strong, and the metal seed layer may not be easily peeled off from the adhesion layer. Therefore, when forming the metal layer, hole defects caused by the peeling between the metal seed layer and the adhesion layer may not be formed, ensuring that the formed semiconductor device may have a substantially high quality and performance stability.

Other aspects of the present disclosure can be understood by those skilled in the art in light of the description, the claims, and the drawings of the present disclosure.

### BRIEF DESCRIPTION OF THE DRAWINGS

FIGS. 1-5 illustrate semiconductor structures corresponding to certain stages for forming a semiconductor device;

FIGS. 6-10 illustrate semiconductor structures corresponding to certain stages for forming an exemplary semiconductor device consistent with various disclosed embodiments of the present disclosure;

FIGS. 11-14 illustrate semiconductor structures corresponding to certain stages for forming another exemplary semiconductor device consistent with various disclosed embodiments of the present disclosure;

FIGS. 15-18 illustrate semiconductor structures corresponding to certain stages for forming another exemplary semiconductor device consistent with various disclosed embodiments of the present disclosure;

FIG. 19 illustrates a flowchart of an exemplary method for forming a semiconductor device consistent with various disclosed embodiments of the present disclosure;

FIG. 20 illustrates a flowchart of another exemplary method for forming a semiconductor device consistent with various disclosed embodiments of the present disclosure; and

FIG. 21 illustrates a flowchart of another exemplary method for forming a semiconductor device consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or the alike parts.

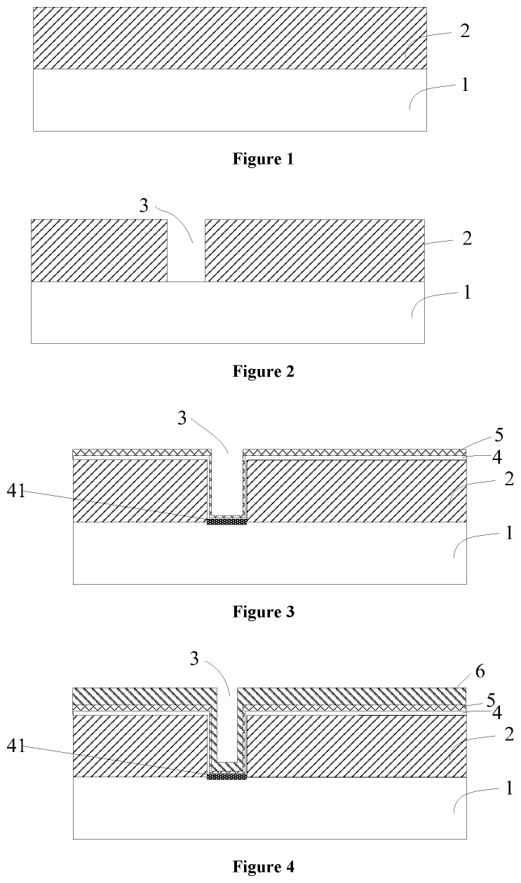

FIGS. 1-5 illustrate semiconductor structures corresponding to certain stages for forming a semiconductor device. Referring to FIG. 1, a substrate 1 is provided, and an interlayer dielectric layer 2 is formed on the substrate 1.

Referring to FIG. 2, the interlayer dielectric layer 2 is etched to form a contact hole 3 in the interlayer dielectric layer 2.

Referring to FIG. 3, a reactive metal layer 4 and a diffusion barrier layer 5 are sequentially formed at a bottom and on a sidewall of the contact hole 3, and on a surface of the interlayer dielectric layer 2. The reactive metal layer 4 reacts with the surface of the substrate 1 to form a silicide layer 41.

Referring to FIG. 4, a metal seed layer 6 is formed on the diffusion barrier layer 5 in the contact hole 3 by a physical vapor deposition process, a chemical vapor deposition process, or a combination thereof.

Referring to FIG. 5, a metal layer 7 is formed on the metal seed layer 6 in the contact hole 3.

The semiconductor device formed by such method has poor performance stability and tends to have failure phenomenon, which limits the application of the semiconductor device. Because the size of the contact hole 3 is small, when forming the metal seed layer 6, the internal structure and internal environment of the contact hole 3 have a strong effect on the metal seed layer 6, which prevents the deposition of the metal seed layer 6. Therefore, the metal seed layer 6 has poor coverage effect on the diffusion barrier layer 5, and the adhesive force between the metal seed layer 6 and the diffusion barrier layer 5 is small. When subsequently forming the metal layer, the metal seed layer tends to be peeled off from the diffusion barrier layer, which causes hole defects at the interface between the metal layer and the contact hole, and causes a degradation of device performance.

When forming a metal seed layer at the bottom and on the sidewall of an adhesion layer by a selective growth method, an adhesive force between the formed metal seed layer and the adhesion layer may be strong, and the metal seed layer may have a desired adhesion effect at the bottom and on the sidewall of the contact hole. Therefore, it may be ensured that when forming the metal layer, hole defects may not be formed at the interface between the contact hole and the metal layer, thereby improving the quality of the formed semiconductor device. The present disclosure provides a semiconductor device and a method for forming the semiconductor device.

### Exemplary Embodiment 1

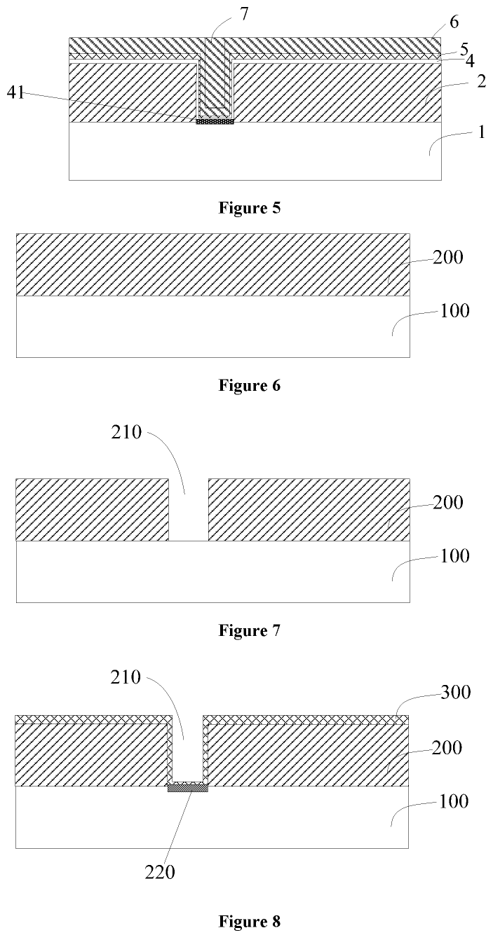

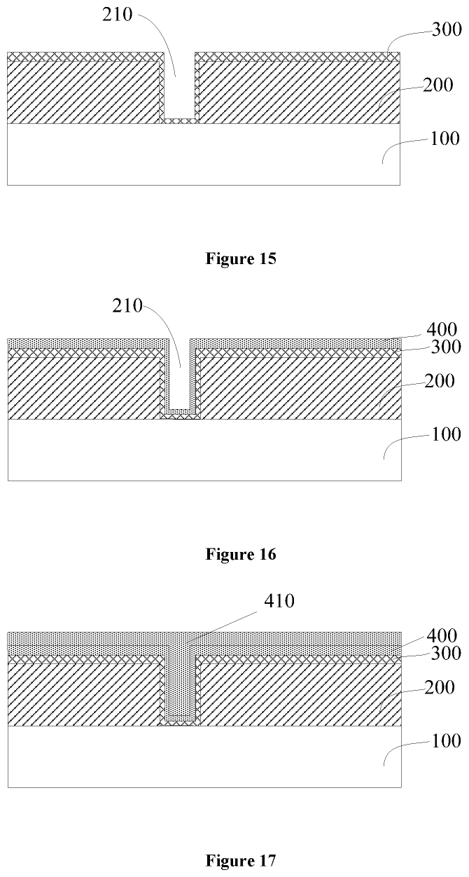

FIG. 19 illustrates a flowchart of a method for forming a semiconductor device consistent with various disclosed embodiments of the present disclosure, and FIGS. 6-10 illustrate semiconductor structures corresponding to certain stages of the fabrication method.

As shown in FIG. 19, at the beginning of the fabrication method, a substrate with certain structures may be provided and an interlayer dielectric layer may be formed (S101). FIG. 6 illustrates a corresponding semiconductor structure.

Referring to FIG. 6, a substrate 100 may be provided, and an interlayer dielectric layer 200 may be formed on the substrate 100. In one embodiment, the substrate 100 may include a base, and a memory device and a logic device on the base.

In one embodiment, the interlayer dielectric layer 200 may be made of silicon oxide. In another embodiment, the interlayer dielectric layer 200 may be made of other insulating materials, such as silicon nitride, silicon boronitride, silicon oxy-carbo-nitride, silicon oxynitride, or a combination thereof.

In one embodiment, the interlayer dielectric layer 200 may be formed on the substrate 100 by a chemical vapor deposition process. Process parameters of the chemical vapor deposition process may include gases including oxygen (O₂), ammonia (NH₃) and N(SiH₃)₃, where a flow rate of oxygen is in a range of approximately 20 sccm-10000 sccm, a flow rate of ammonia (NH₃) is in a range of approximately 20 sccm-10000 sccm, and a flow rate of N(SiH₃)₃ is in a range of approximately 20 sccm-10000 sccm; a chamber pressure in a range of approximately 0.01 Torr-10 Torr; and a temperature in a range of approximately 30° C.-90° C.

Returning to FIG. 19, after providing the substrate, a contact hole may be formed (S102). FIG. 7 illustrates a corresponding semiconductor structure.

Referring to FIG. 7, a contact hole 210 may be formed in the interlayer dielectric layer 200 by etching the interlayer dielectric layer 200. A bottom of the contact hole 210 may expose a portion of the surface of the substrate 100.

In one embodiment, the contact hole 210 may be formed by a dry etching process. Parameters of the dry etching process may include: gases including CF₄ and CH₃F, where a flow rate of CF₄ is in a range of approximately 20 sccm-200 sccm, and a flow rate of CH₃F is in a range of approximately 20 sccm-50 sccm; a source RF power in a range of approximately 200 W-500 W; and a chamber pressure in a range of approximately 1 Torr-10 Torr.

In one embodiment, the contact hole 210 may expose a source region and/or a drain region on the substrate 100. In another embodiment, the contact hole 210 may expose a gate structure on the substrate 100.

Returning to FIG. 19, after forming the contact hole, a single-layer adhesion layer may be formed (S103). FIG. 8 illustrates a corresponding semiconductor structure.

Referring to FIG. 8, a single-layer adhesion layer 300 may be formed at the bottom and on the sidewall of the contact hole 210. In one embodiment, the single-layer adhesion layer 300 may be made of tungsten (W). In another embodiment, the single-layer adhesion layer 300 may be made of tantalum (Ta).

In one embodiment, the single-layer adhesion layer 300 may be extended onto the interlayer dielectric layer 200. In one embodiment, the single-layer adhesion layer 300 may be formed by an atomic layer deposition (ALD) method. In another embodiment, the single-layer adhesion layer 300 may be formed by a chemical vapor deposition (CVD) method, a physical vapor deposition (PVD) method, or a combination thereof.

In one embodiment, the reason why the single-layer adhesion layer 300 is formed by the atomic layer deposition method may include that the single-layer adhesion layer 300 formed by the atomic layer deposition method may have a substantially high density, which may effectively block the diffusion of ions.

In one embodiment, the formed single-layer adhesion layer 300 may contain a substantially large amount of charges and polar bonds on the surface under the reaction of the precursor process. Therefore, when subsequently forming a metal seed layer by a selective growth method, an adsorption force for adsorbing the metal seed layer may be provided to ensure that the metal seed layer with desired quality may be formed at the bottom and on the sidewall of the contact hole. Meanwhile, the adhesive force between the single-layer adhesion layer 300 and the metal seed layer may be substantially strong.

In one embodiment, before forming the single-layer adhesion layer 300, the method may further include forming a reactive metal layer (not illustrated in the Figure) at the bottom and on the sidewall of the contact hole 210, and forming a diffusion barrier layer (not illustrated in the Figure) on the reactive metal layer. The formed reactive metal layer may react with the substrate 100 to form a silicide layer 220. The silicide layer 220 may be formed by a thermal treatment process. After forming the silicide layer 220, the unreacted metal layer and diffusion barrier layer may be removed.

In one embodiment, the reason for removing the unreacted metal layer and diffusion barrier layer may include that the unreacted metal layer and diffusion barrier layer may have a substantially high resistance. When subsequently forming the metal layer, a contact resistance between a metal layer and a device at the bottom of the contact hole may be substantially high, such that the semiconductor device formed by such method may tend to have a heat-generation issue and reduced operating speed during operation, thereby limiting the application of the semiconductor device.

Returning to FIG. 19, after forming the single-layer adhesion layer, a metal seed layer may be formed (S104). FIG. 9 illustrates a corresponding semiconductor structure.

Referring to FIG. 9, a metal seed layer 400 may be formed at the bottom and on the sidewall of the single-layer adhesion layer 300 by a selective growth method. In one embodiment, the metal seed layer 400 may be made of cobalt (Co).

In one embodiment, process parameters of the selective growth method may include: an organic source including CoDCP (e.g., CpCo(Co)₂ or (C₅H₅)Co(CO)₂); reaction gases including hydrogen (H₂), ammonia (NH₃) and argon (Ar), where a flow rate of hydrogen (H₂) is in a range of approximately 1000 sccm-8000 sccm, a flow rate of ammonia (NH₃) is in a range of approximately 1000 sccm-5000 sccm, and a flow rate of argon (Ar) is in a range of approximately 10 sccm-500 sccm; a source RF power in a range of approximately 100 W-2000 W, a temperature in a range of approximately 100° C.-400° C., and a pressure in a range of approximately 10 Torr-40 Torr.

In one embodiment, the metal seed layer 400 formed by the selective growth method may have a substantially large amount of polar bonds or charges on the surface, and at the same time, the formed single-layer adhesion layer 300 may also have a substantially large amount of polar bonds or charges on the surface due to the action of the precursor process. Therefore, the metal seed layer 400 and the single-layer adhesion layer 300 may attract each other due to surface properties. When forming the metal seed layer 400, the metal seed layer 400 may be easily adhered onto the single-layer adhesion layer 300. At the same time, the single-layer adhesion layer 300 may also provide adsorption force for filling the metal seed layer 400, such that the metal seed layer 400 may be substantially well adhered at the bottom and on the sidewall of the contact hole 210. Therefore, the formed metal seed layer 400 in the contact hole 210 may not only have a substantially high formation quality, but also have a substantially large adhesive force with the single-layer adhesion layer 300 due to similar surface properties thereof.

In one embodiment, the precursor process may include a process for processing each surface of the single-layer adhesion layer 300 before forming the metal seed layer 400. In one embodiment, the metal seed layer 400 may also be extended onto the single-layer adhesion layer 300 on the interlayer dielectric layer 200.

Returning to FIG. 19, after forming the metal seed layer, a metal layer may be formed (S105). FIG. 10 illustrates a corresponding semiconductor structure.

Referring to FIG. 10, a metal layer 410 may be formed on the metal seed layer 400, and the metal layer 410 may fill the contact hole 210. In one embodiment, the metal layer 410 may be made of cobalt (Co).

In one embodiment, due to the strong adhesive force between the formed metal seed layer 400 and the single-layer adhesion layer 300, when forming the metal layer 410, the metal seed layer 400 may not be easily peeled off from the single-layer adhesion layer 300. Therefore, it may be ensured that when forming the metal layer 410, hole defects may not be formed at the interface between the metal layer 410 and the contact hole 210, thereby improving the electrical performance and yield of the formed semiconductor device.

In one embodiment, the metal layer 410 may be formed by an electrochemical plating method. The process of forming the metal layer 410 by the electrochemical plating method may be a conventional process method, which may not be repeated herein.

In one embodiment, after forming the metal layer 410, an annealing treatment may be performed, and an annealing temperature may be in a range of approximately 400° C.-450° C. After performing the annealing treatment, an amorphous phase of W/Co—W—Si/WSi may be formed at the interface between the metal layer and the contact hole, and may serve as a diffusion barrier layer of the metal layer. The amorphous phase of W/Co—W—Si/WSi may not only prevent the diffusion of ions, but also reduce the contact resistance of the formed semiconductor device due to a substantially small resistance of the amorphous phase of the W/Co—W—Si/WSi, thereby improving the device performance.

In one embodiment, after the metal layer 410 is formed, the metal layer 410 may be planarized by a chemical mechanical polishing (CMP) method.

Correspondingly, the present disclosure also provides a semiconductor device formed by the above-disclosed method. The semiconductor device may include a substrate 100, and an interlayer dielectric layer 200 disposed on the substrate 100. The interlayer dielectric layer may include a contact hole exposing a portion of the surface of the substrate. The semiconductor device may also include a silicide layer 220 located on the substrate 100 in the contact hole 210, and a single-layer adhesion layer 300 disposed at the bottom and on the sidewall of the contact hole 210. Further, the semiconductor device may include a metal seed layer 400 disposed at the bottom and on the sidewall of the single-layer adhesion layer 300 in the contact hole 210, and a metal layer 410 disposed on the metal seed layer 400 and filling the contact hole 210.

### Exemplary Embodiment 2

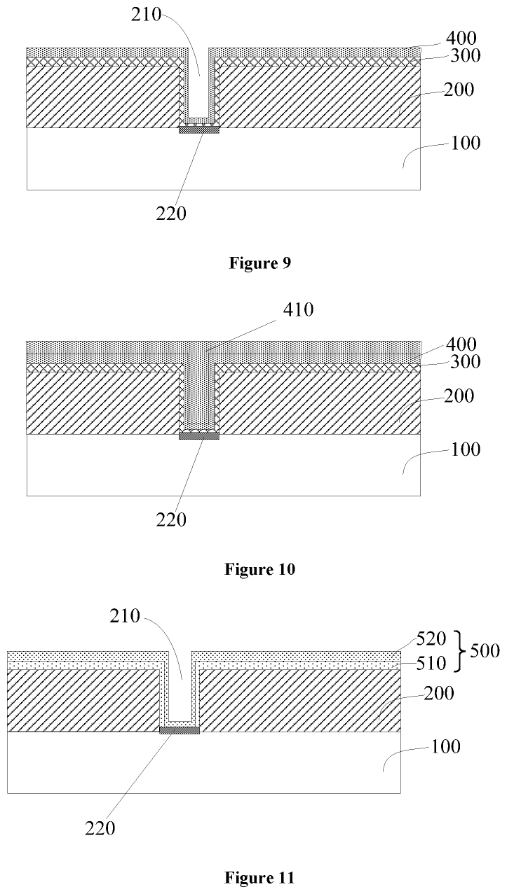

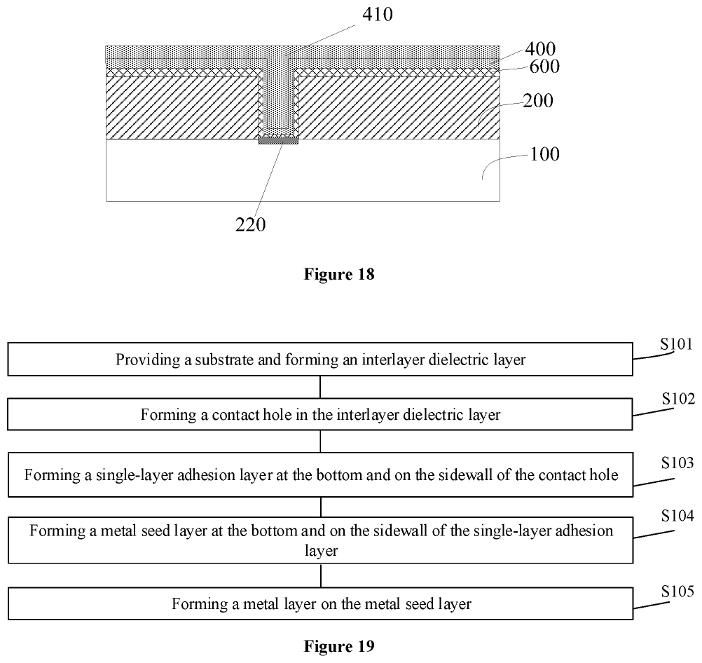

FIG. 20 illustrates a flowchart of another method for forming a semiconductor device consistent with various disclosed embodiments of the present disclosure, and FIGS. 11-14 illustrate semiconductor structures corresponding to certain stages of the fabrication method. The difference between the Embodiment 2 and the Embodiment 1 may include that the adhesion layer in Embodiment 2 may be a multi-layer adhesion layer.

As shown in FIG. 20, at the beginning of the fabrication method, a substrate may be provided and a contact hole may be formed (S201). The processes for providing the substrate and forming the contact hole in Embodiment 2 may be the same as in Embodiment 1, and details thereof may refer to FIGS. 6-7.

Returning to FIG. 20, after forming the contact hole, an adhesion layer may be formed (S202). FIG. 11 illustrates a corresponding semiconductor structure.

Referring to FIG. 11, an adhesion layer 500 may be formed at the bottom and on the sidewall of the contact hole 210. In one embodiment, the adhesion layer 500 may be a multi-layer adhesion layer. The multi-layer adhesion layer 500 may include a reactive metal layer 510 and a first diffusion barrier layer 520.

In one embodiment, the process for forming the adhesion layer 500 may include forming the reactive metal layer 510 at the bottom and on the sidewall of the contact hole 210, and forming the first diffusion barrier layer 520 on the reactive metal layer 510. In one embodiment, the reactive metal layer 510 may be made of titanium (Ti). In another embodiment, the reactive metal layer 510 may be made of other metals, such as cobalt, NiPt, or a combination thereof.

In one embodiment, the reactive metal layer 510 may react with the substrate 100 to form the silicide layer 220. In one embodiment, the silicide layer 220 may be formed by a directed self-assembly (DSA) process.

In one embodiment, the first diffusion barrier layer 520 may be made of TiN. In another embodiment, the first diffusion barrier layer 520 may be made of TaN, etc.

In one embodiment, the purpose of forming the first diffusion barrier layer 520 on the surface of the reactive metal layer 510 may include that during the process of forming the silicide layer 220, the reactive metal layer 510 may be prevented from being oxidized, hole defects may be prevented from being formed in the silicide layer, and the electrical performance of the formed semiconductor device may be prevented from being affected.

Returning to FIG. 20, after forming the adhesion layer, a second diffusion barrier layer may be formed (S203). FIG. 12 illustrates a corresponding semiconductor structure.

Referring to FIG. 12, after forming the first diffusion barrier layer 520, a second diffusion barrier layer 530 may be formed on the first diffusion barrier layer 520.

In one embodiment, after forming the silicide layer 220 and before forming the metal seed layer 400, a new diffusion barrier layer, i.e., the second diffusion barrier layer 530, may be formed on the first diffusion barrier layer 520. The reason for forming the second diffusion barrier layer 530 may include that in the process of forming the silicide layer 220 by the directed self-assembly (DSA) process, the material inside the first diffusion barrier layer 520 may also be directionally self-assembled. Therefore, a gap or damage may be formed at the surface of the first diffusion barrier layer 520, which may affect the performance of the first diffusion barrier layer 520 for blocking the diffusion of ions. Thus, the second diffusion barrier layer 530 may be required to improve the blocking ability of the diffusion barrier layer and to improve the blocking effect on diffusion of ions.

Returning to FIG. 20, after forming the second diffusion barrier layer, a metal seed layer may be formed (S204). FIG. 13 illustrates a corresponding semiconductor structure.

Referring to FIG. 13, a metal seed layer 400 may be formed at the bottom and on the sidewall of the adhesion layer 500 by a selective growth method. In one embodiment, the metal seed layer 400 may be formed at the bottom and on the sidewall of the second diffusion barrier layer 530. The process parameters for forming the metal seed layer 400 in Embodiment 2 may be the same as in Embodiment 1, which are not repeated herein.

Returning to FIG. 20, after forming the metal seed layer, a metal layer may be formed (S205). FIG. 14 illustrates a corresponding semiconductor structure.

Referring to FIG. 14, a metal layer 410 may be formed on the metal seed layer 400, and the metal layer 410 may fill the contact hole 210. In one embodiment, after the metal layer 410 is formed, the metal layer 410 may be planarized by a chemical mechanical polishing method.

Correspondingly, the present disclosure also provides a semiconductor device formed by the above-disclosed method. The semiconductor device may include a substrate 100, and an interlayer dielectric layer 200 disposed on the substrate 100. The interlayer dielectric layer may include a contact hole exposing a portion of the surface of the substrate. The semiconductor device may also include a silicide layer 220 located on the substrate 100 in the contact hole 210. In addition, the semiconductor device may include an adhesion layer 500. The adhesion layer 500 may include a reactive metal layer 510 and a first diffusion barrier layer 520. The reactive metal layer 510 may be formed at the bottom and on the sidewall of the contact hole 210, and the first diffusion barrier layer 520 may be formed on the reactive metal layer 510. Moreover, the semiconductor device may include a second diffusion barrier layer 530 formed on the first diffusion barrier layer 520. Further, the semiconductor device may include a metal seed layer 400 disposed at the bottom and on the sidewall of the second diffusion barrier layer 530 in the contact hole 210, and a metal layer 410 disposed on the metal seed layer 400 and filling the contact hole 210.

### Exemplary Embodiment 3

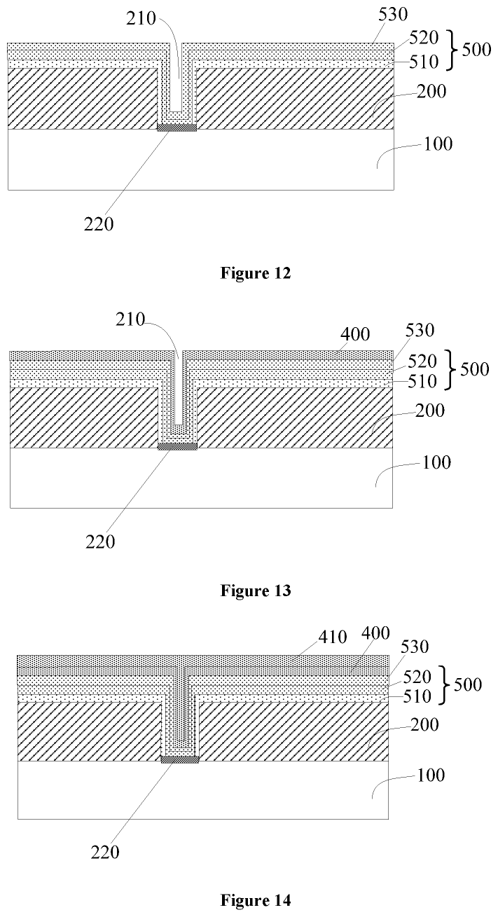

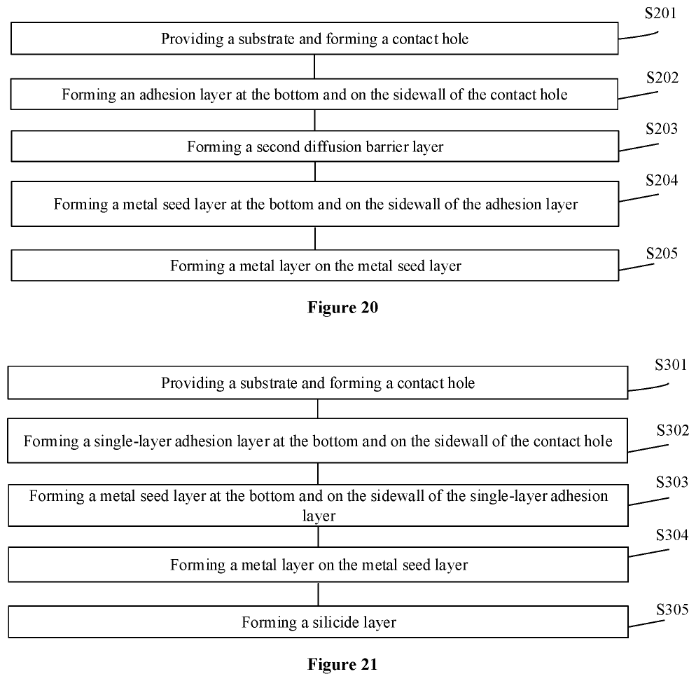

FIG. 21 illustrates a flowchart of another method for forming a semiconductor device consistent with various disclosed embodiments of the present disclosure, and FIGS. 15-18 illustrate semiconductor structures corresponding to certain stages of the fabrication method. The difference between Embodiment 3 and Embodiment 1 may include that the single-layer adhesion layer in Embodiment 3 may be made of titanium, and the silicide layer may be formed after forming the metal layer.

As shown in FIG. 21, at the beginning of the fabrication method, a substrate may be provided and a contact hole may be formed (S301). The processes for providing the substrate and forming the contact hole in Embodiment 3 may be the same as in Embodiment 1, and details thereof may refer to FIGS. 6-7.

Returning to FIG. 21, after forming the contact hole, a single-layer adhesion layer may be formed (S302). FIG. 15 illustrates a corresponding semiconductor structure.

Referring to FIG. 15, a single-layer adhesion layer 300 may be formed at the bottom and on the sidewall of the contact hole 210. In one embodiment, the single-layer adhesion layer 300 may be extended onto the surface of the interlayer dielectric layer 200.

In one embodiment, the single-layer adhesion layer 300 may be made of titanium. In one embodiment, the single-layer adhesion layer 300 may be formed by an atomic layer deposition (ALD) method. In other embodiments, the single-layer adhesion layer 300 may be formed by a chemical vapor deposition (CVD) method, a physical vapor deposition (PVD) method, or a combination thereof.

In one embodiment, the single-layer adhesion layer 300 made of titanium and formed by the atomic layer deposition method may have a substantially high density, which may effectively block the diffusion of ions.

Returning to FIG. 21, after forming the single-layer adhesion layer, a metal seed layer may be formed (S303). FIG. 16 illustrates a corresponding semiconductor structure.

Referring to FIG. 16, a metal seed layer 400 may be formed at the bottom and on the sidewall of the single-layer adhesion layer 300 by a selective growth method. The process parameters for forming the metal seed layer 400 in Embodiment 3 may be the same as in Embodiment 1, which are not repeated herein.

Returning to FIG. 21, after forming the metal seed layer, a metal layer may be formed (S304). FIG. 17 illustrates a corresponding semiconductor structure.

Referring to FIG. 17, a metal layer 410 may be formed on the metal seed layer 400, and the metal layer 410 may fill the contact hole 210.

Returning to FIG. 21, after forming the metal layer, a silicide layer may be formed (S305). FIG. 18 illustrates a corresponding semiconductor structure.

Referring to FIG. 18, after forming the metal layer 410, a silicide layer 220 may be formed on the substrate 100 in the contact hole 210. In one embodiment, a thermal treatment may be performed on the substrate 100 after the metal layer 410 is formed, and the silicide layer 220 may be formed on the substrate 100 in the contact hole 210.

In one embodiment, after the metal layer is formed, the single-layer adhesion layer 300 may chemically react with the substrate 100 to form the silicide layer 220, thereby ensuring that the formed silicide layer 220 may have a substantially high formation quality. Because the metal seed layer and metal layer formed on the single-layer adhesion layer 300 protect the single-layer adhesion layer 300, when the single-layer adhesion layer 300 reacts with the substrate 100 to form the silicide layer 220 in the thermal treatment process, the metal seed layer and the metal layer may separate the single-layer adhesion layer 300 from oxygen, such that the single-layer adhesion layer 300 may not be oxidized during the process of forming the silicide layer 220. Therefore, the quality of the formed silicide layer may be ensured, and the device performance of the formed semiconductor device may be improved.

The disclosed embodiments may have following beneficial effects. The metal seed layer may be formed at the bottom and on the sidewall of the contact hole by a selective growth method. The formed metal seed layer may be effectively adhered to the adhesion layer. When forming the metal layer on the metal seed layer, the metal seed layer may not be easily peeled off from the adhesion layer. Therefore, when forming the metal layer, the interface between the metal layer and the contact hole may have a desired formation quality, and hole defects may not be formed at the interface, thereby improving the device performance and yield of the formed semiconductor device.

The surface of the metal seed layer formed by the selective growth method may have similar properties to the surface of the adhesion layer. When forming the metal seed layer, an adsorption force for adsorbing the metal seed layer may be formed at the surface of the adhesion layer. Therefore, the metal seed layer may substantially easily fill the bottom of the contact hole, and the formed metal seed layer may have desired adhesion quality. At the same time, the adhesive force between the adhesion layer and the metal seed layer may be substantially strong, and the metal seed layer may not be easily peeled off from the adhesion layer. Therefore, when forming the metal layer, hole defects caused by the peeling between the metal seed layer and the adhesion layer may not be formed, ensuring that the formed semiconductor device may have a substantially high quality and performance stability.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A method for forming a semiconductor device, comprising:
providing a substrate;
forming an interlayer dielectric layer on the substrate;
forming a contact hole by etching the interlayer dielectric layer, wherein the contact hole exposes a portion of the surface of the substrate;
forming an adhesion layer at a bottom and on a sidewall of the contact hole;
forming a metal seed layer at a bottom and on a sidewall of the adhesion layer by a selective growth method; and
forming a metal layer on the metal seed layer, wherein the metal layer fills the contact hole.

2. The method according to claim 1, wherein process parameters of the selective growth method include:
an organic source including (C₅H₅)Co(CO)₂,
a reaction gas including hydrogen, ammonia and argon, wherein a flow rate of hydrogen is in a range of approximately 1000 sccm-8000 sccm, a flow rate of ammonia is in a range of approximately 1000 sccm-5000 sccm, and a flow rate of argon is in a range of approximately 10 sccm-500 sccm,
a source RF power in a range of approximately 100 W-2000 W,
a temperature in a range of approximately 100° C.-400° C., and
a pressure in a range of approximately 10 Torr-40 Torr.

3. The method according to claim 1, wherein:
the metal seed layer is made of cobalt.

4. The method according to claim 1, wherein:
the metal layer is made of cobalt.

5. The method according to claim 1, wherein:
the metal layer is formed by an electrochemical plating method.

6. The method according to claim 1, wherein:
the adhesion layer is one of a single-layer adhesion layer and a multi-layer adhesion layer.

7. The method according to claim 6, wherein:
when the adhesion layer is the multi-layer adhesion layer, the multi-layer adhesion layer includes a reactive metal layer and a first diffusion barrier layer, wherein forming the multi-layer adhesion layer includes:
forming the reactive metal layer at the bottom and on the sidewall of the contact hole, and
forming the first diffusion barrier layer on the reactive metal layer.

8. The method according to claim 7, after forming the first diffusion barrier layer, further including:
forming a second diffusion barrier layer on the first diffusion barrier layer.

9. The method according to claim 6, wherein:
the single-layer adhesion layer is made of tungsten, tantalum, titanium, or a combination thereof.

10. The method according to claim 9, wherein, when the single-layer adhesion layer is made of one of tungsten and tantalum, before forming the single-layer adhesion layer, the method further includes:
forming a silicide layer on the substrate in the contact hole.

11. The method according to claim 9, wherein, when the single-layer adhesion layer is made of titanium, after forming the metal layer, the method further includes:
forming a silicide layer on the substrate in the contact hole.

12. The method according to claim 6, wherein:
forming the single-layer adhesion layer includes an atomic layer deposition method.

13. A semiconductor device, comprising:
a substrate;
an interlayer dielectric layer on the substrate, wherein the interlayer dielectric layer includes a contact hole exposing a portion of the surface of the substrate;
an adhesion layer at a bottom and on a sidewall of the contact hole in the interlayer dielectric layer;
a metal seed layer at a bottom and on a sidewall of the adhesion layer; and
a metal layer on the metal seed layer, wherein the metal layer fills the contact hole.

14. The semiconductor device according to claim 13, wherein:
the metal seed layer is made of cobalt.

15. The semiconductor device according to claim 13, wherein:
the metal layer is made of cobalt.

16. The semiconductor device according to claim 13, wherein:
the adhesion layer is one of a single-layer adhesion layer and a multi-layer adhesion layer.

17. The semiconductor device according to claim 16, wherein:
the multi-layer adhesion layer includes a reactive metal layer and a first diffusion barrier layer.

18. The semiconductor device according to claim 17, further including:
a second diffusion barrier layer on the first diffusion barrier layer.

19. The semiconductor device according to claim 16, wherein:
the single-layer adhesion layer is made of tungsten, tantalum, titanium, or a combination thereof.

20. The semiconductor device according to claim 1, further including:
a silicide layer on the substrate and under the adhesion layer.
